(19) United States
(12) Patent Application Publication
(10) Pub. No.: US 2026/0229461 A1
(43) Pub. Date: Aug. 6, 2026

(54) SUBSTRATE PROCESSING APPARATUS INCLUDING SHARED RF GENERATOR

(71) Applicant: ASM IP Holding B.V., Almere (NL)

(72) Inventors: JongSu Kim, Hwaseong-si (KR); DaeYoun Kim, Seo-gu (KR); Tomohiro Arakawa, Sagamihara-shi (JP)

(21) Appl. No.: 19/032,282

(22) Filed: Jan. 20, 2025

Related U.S. Application Data
(60) Provisional application No. 63/623,947, filed on Jan. 23, 2024.

(51) Int. Cl. H01J 37/32

(52) U.S. Cl. CPC H01J 37/32183; H01J 37/32724; H01J 37/32889; H01J 37/32899; H01J 2237/3321

(57) ABSTRACT

A substrate processing apparatus is disclosed. Exemplary substrate processing apparatus may comprise a plurality of anneal chambers; a shared RF generator configured to generate a plasma to the anneal chambers; wherein the shared RF generator is electrically coupled to the anneal chambers via a RF divider; wherein the RF divider is provided with a plurality of RF cables, each of the RF cables is electrically coupled to each of the anneal chambers respectively.

### CROSS-REFERENCE TO RELATED APPLICATIONS

This application claims priority to U.S. Provisional Patent Application Ser. No. 63/623,947 filed Jan. 23, 2024 titled SUBSTRATE PROCESSING APPARATUS INCLUDING SHARED RF GENERATOR, the disclosure of which is hereby incorporated by reference in its entirety.

### FIELD OF INVENTION

The present disclosure relates generally to a substrate processing apparatus. More particularly, exemplary embodiments of the present disclosure relate to a substrate processing apparatus including a shared RF generator.

### BACKGROUND OF THE DISCLOSURE

Substrate processing apparatuses are widely used to process substrates, for example, to form thin films on a substrate. The semiconductor processing apparatus often includes (i) a plurality of process modules; (ii) a substrate handling chamber having a substrate handling robot; and (iii) a load lock chamber for loading or unloading the substrate.

Each process module may include 4 reaction chambers. An exemplary substrate processing apparatus including 4 reaction chambers, which is known as a Quad Chamber Module (QCM), is disclosed in U.S. Pat. No. 10,777,445, which is hereby incorporated by reference.

Each chamber may include a susceptor to support a substrate. Processes such as film formation, film modification, etching, annealing, or the like may be performed on the substrate in each chamber. These processes may be performed by a plasma apparatus, such as a Plasma Enhanced Chemical Vapor Deposition (PECVD) apparatus, a Plasma Enhanced Atomic Layer Deposition Process (PEALD) apparatus, or the like.

An RF generator generates an RF power in the plasma apparatus. The RF power is supplied to an electrode via a matching unit and a RF cable in the reaction chamber, thereby generating a plasma in the reaction chamber.

Currently, each chamber has its own RF generator and matching unit, thereby increasing the cost of the process module.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a substrate processing apparatus is provided. The substrate processing apparatus may comprise a plurality of anneal chambers; a shared RF generator configured to generate a plasma to the anneal chambers; wherein the shared RF generator is electrically coupled to the anneal chambers via a RF divider; wherein the RF divider is provided with a plurality of RF cables, each of the RF cables is electrically coupled to each of the anneal chambers respectively.

In accordance with further exemplary embodiments of the disclosure, the plasma may be generated before a substrate is provided to the anneal chamber.

In accordance with further exemplary embodiments of the disclosure, a temperature of the anneal chamber may be between 100° C. and 800° C.

In accordance with further exemplary embodiments of the disclosure, the anneal chamber may further comprise a susceptor heater constructed and arranged to support a substrate, wherein the susceptor heater may comprises a ceramic. The ceramic may comprise at least one of Al2O3, AlN, SiC, or Si3N4.

In accordance with further exemplary embodiments of the disclosure, a shared RF matcher may be disposed between the shared RF generator and the RF divider.

In accordance with further exemplary embodiments of the disclosure, an ammeter may be disposed between the shared RF generator and the RF divider.

In accordance with further exemplary embodiments of the disclosure, the ammeter may be configured to measure a current.

In accordance with further exemplary embodiments of the disclosure, a controller may be electrically coupled to the ammeter, wherein the controller may be configured to generate an alert when an output of the ammeter deviates from a normal value.

In accordance with further exemplary embodiments of the disclosure, the controller may be configured to stop an operation of the shared RF generator based on the output of the ammeter.

In accordance with further exemplary embodiments of the disclosure, the substrate processing apparatus may further comprise a plurality of deposition chambers; a plurality of RF generator configured to generate a 2nd plasma to the deposition chambers; wherein each of the RF generator may be electrically coupled to the deposition chamber.

In accordance with further exemplary embodiments of the disclosure, the 2nd plasma may be generated when a gapfill deposition process may be performed in the deposition chamber.

In accordance with further exemplary embodiments of the disclosure, a temperature of the deposition chamber may be between 50° C. and 550° C.

In accordance with further exemplary embodiments of the disclosure, the deposition chamber may further comprise a 2nd susceptor heater constructed and arranged to support a substrate, wherein the 2^{nd} susceptor heater may comprises aluminum.

In accordance with further exemplary embodiments of the disclosure, an anneal chamber module may comprise the plurality of anneal chambers and a deposition chamber module may comprise the plurality of deposition chambers.

In accordance with further exemplary embodiments of the disclosure, the substrate processing apparatus may further comprise: a substrate handling chamber having a plurality of sides, wherein the anneal chamber module may be attached to one of the sides; wherein the deposition chamber module may be attached to one of the sides; a backend robot for transferring a substrate, the backend robot being disposed in the substrate handling chamber; and a load lock chamber for loading or unloading the substrate, the load lock chamber being attached to one of the sides.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a schematic plan view of a substrate processing apparatus with quad chamber modules in accordance with exemplary embodiments of the disclosure.

FIG. 2 illustrate a schematic view of a quad chamber module with anneal chambers in accordance with exemplary embodiments of the disclosure.

FIG. 3 illustrate a schematic view of a quad chamber module with deposition chambers in accordance with exemplary embodiments of the disclosure.

FIG. 4 illustrates a plasma apparatus in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

In this disclosure, “gas” may include material that is a gas at normal temperature and pressure, a vaporized solid and/or a vaporized liquid, and may be constituted by a single gas or a mixture of gases, depending on the context. A gas introduced without passing through a gas supply unit, such as a shower plate, or the like, may be used for, e.g., sealing the reaction space, and may include a seal gas, such as a rare or other inert gas. The term inert gas, carrier gas, and dilution gas refer to a gas that does not take part in a chemical reaction to an appreciable extent and/or a gas that may excite a precursor when plasma power is applied.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

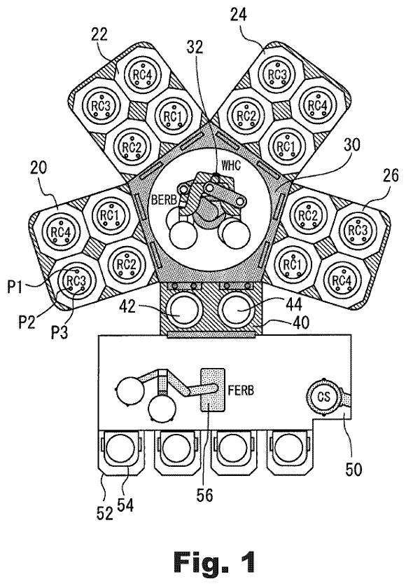

FIG. 1 is a schematic plan view of a substrate processing apparatus with quad chamber modules in an embodiment of the present invention. The substrate processing apparatus may comprise: (i) four process modules 20, 22, 24, 26, each having four reaction chambers RC1, RC2, RC3, RC4; (ii) a substrate handling chamber 30 including two back end robots 32 (substrate handling robots); and (iii) a load lock chamber 40 for loading or unloading two substrates simultaneously, the load lock chamber 40 being attached to the one additional side of the substrate handling chamber 30, wherein each back end robot 32 is accessible to the load lock chamber 40. Each of the back end robots 32 may have at least two end-effectors accessible to the two reaction chambers of each unit simultaneously, said substrate handling chamber 30 having a polygonal shape having four sides corresponding to and being attached to the four process modules 20, 22, 24, 26, respectively, and one additional side for a load lock chamber 40, all the sides being disposed on the same plane. The interior of each process modules 20, 22, 24, 26 and the interior of the load lock chamber 40 may be isolated from the interior of the substrate handling chamber 30 by a gate valve.

In some embodiments, a controller (not shown) may store software programmed to execute sequences of substrate transfer, for example. The controller may also: check the status of each process chamber; position substrates in each process chamber using sensing systems; control a gas box; control an electric box for each module; control a front end robot 56 in an equipment front end module based on a distribution status of substrates stored in FOUP 52 and the load lock chamber 40; control the back end robots 32; and control the control gate valves and other valves.

A skilled artisan may appreciate that the apparatus may include one or more controller(s) programmed or otherwise configured to cause the anneal and deposition processes described elsewhere herein to be conducted. The controller(s) may communicate with the various power sources, heating systems, pumps, robotics, gas flow controllers, or valves, as will be appreciated by the skilled artisan.

In some embodiments, the apparatus may have any number of chambers and process modules greater than one (e.g., 2, 3, 4, 5, 6, or 7). In FIG. 1, the apparatus has sixteen reaction chambers, but it may have 20 or more. In some embodiments, the reaction chambers of the modules may be any suitable reactors for processing or treating wafers, including anneal reactors, CVD reactors (such as plasma-enhanced CVD reactors and thermal CVD reactors) or ALD reactors (such as plasma-enhanced ALD reactors and thermal ALD reactors). Typically, the reaction chambers may be deposition chambers for depositing a film or layer on a wafer and anneal chambers for annealing the film or layer. The process module 20 may be a deposition chamber module. The process module 22 may be a anneal chamber module.

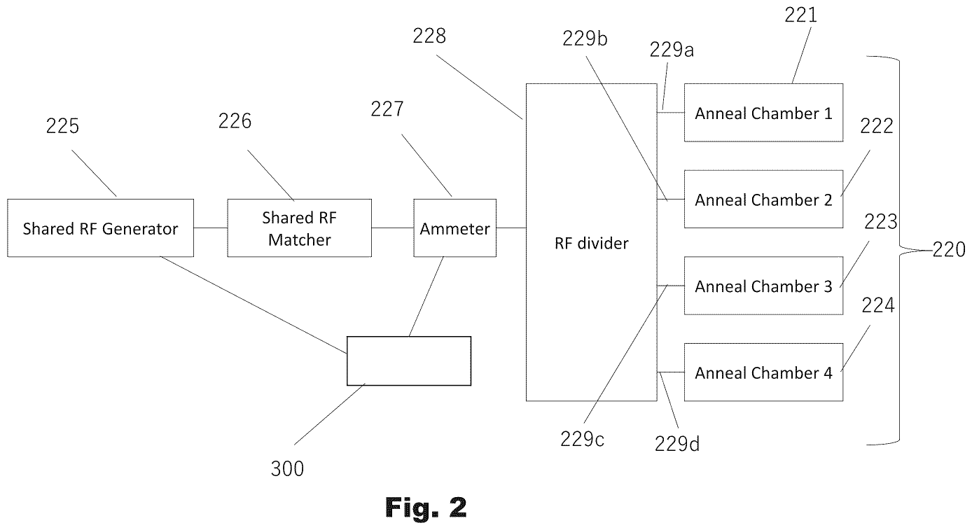

FIG. 2 illustrate a schematic view of a quad chamber module with anneal chambers in accordance with exemplary embodiments of the disclosure. A anneal chamber module 220 may comprises four anneal chambers 221, 222, 223, 224. A shared RF generator 225 may be configured to generate a plasma to the anneal chambers 221, 222, 223, 224.

The shared RF generator 225 may be electrically coupled to the anneal chambers 221, 222, 223, 224 via a RF divider 228. The RF divider 228 may be provided with four RF cables 229a to 229d. Each of the RF cables 229a to 229d may be electrically coupled to each of the anneal chambers 221, 222, 223, 224 respectively. A shared RF matcher 226 may be disposed between the shared RF generator 225 and the RF divider 228.

The plasma may be generated before a substrate is provided to the anneal chamber. A precoating process using the plasma may be performed in the anneal chamber before the substrate is provided to the anneal chamber.

A temperature of the anneal chamber may be between 100° C. and 800° C. An annealing process may be performed after the substrate is provided to the annealing chamber.

An ammeter 227 may be disposed between the shared RF generator 225 and the RF divider 228. The ammeter 227 may be configured to measure a current. A controller 300 may be electrically coupled to the ammeter 227. The controller 300 may be configured to generate an alert when an output of the ammeter 227 deviates from a normal value. The output may deviate from the normal value, for example, when a RF cable is disconnected, or the cable connection is loose. The controller 300 may be configured to stop an operation of the shared RF generator 225 based on the output of the ammeter 227.

The shared RF generator 225, the shared RF matcher 226, and the ammeter 227 may be configured as a single RF unit. The ammeter 227 may be built into the shared RF matcher 226.

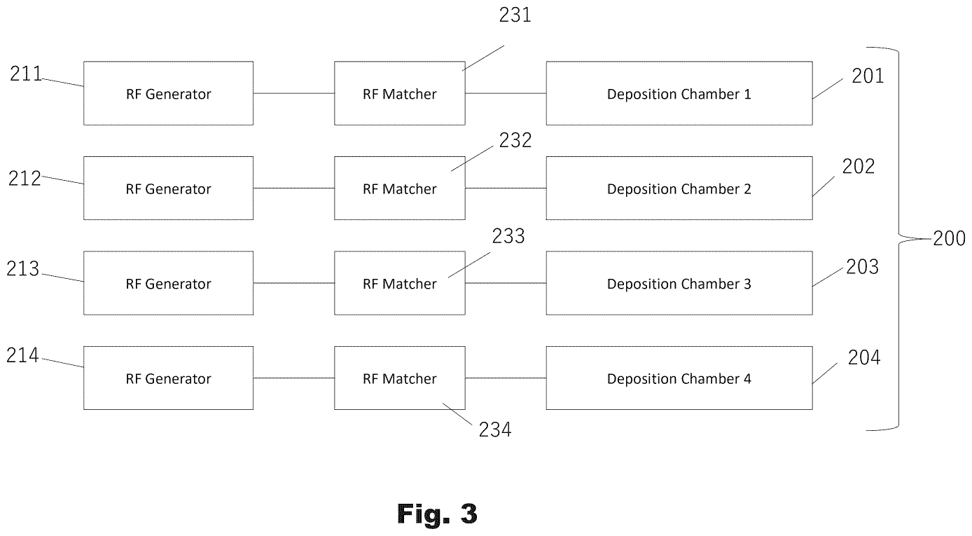

FIG. 3 illustrate a schematic view of a quad chamber module with deposition chambers in accordance with exemplary embodiments of the disclosure. A deposition chamber module 200 may comprises four deposition chambers 201, 202, 203, 204. Each of RF generators 211, 212, 213, 214 may be configured to generate a 2^{nd} plasma to each of the deposition chambers 201, 202, 203, 204 respectively.

The 2^{nd} plasma may be generated when a gapfill deposition process may be performed in the deposition chamber. A substrate in the deposition chamber may be transferred to the anneal chamber module via the substrate handling chamber 30 by the back end robots 32 after the gapfill deposition process is completed. A material on the substrate deposited by the gapfill deposition process may be annealed in the anneal chamber. The material may comprise a carbon, silicon carbide, silicon oxide (SiOx), and silicon nitride (SiNx). A temperature of the deposition chamber may be between 50° C. and 550° C., which may be lower than a temperature of the anneal chamber.

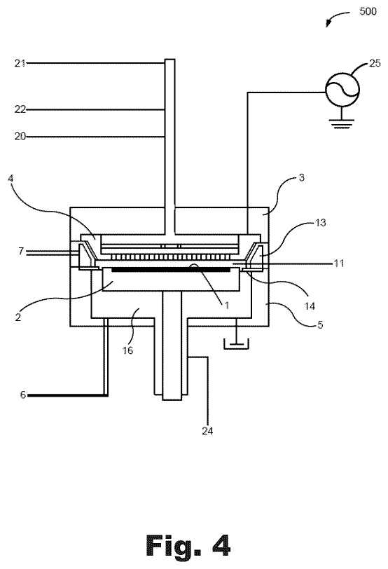

FIG. 4 illustrates a plasma apparatus 500 in accordance with exemplary embodiments of the disclosure is illustrated. The plasma apparatus 500 may be used to perform one or more steps or sub steps as described herein and/or to form one or more structures or portions thereof as described herein.

The plasma apparatus 500 may include a pair of electrically conductive flat-plate electrodes 4, 2 in parallel and facing each other in an interior 11 (reaction zone) of a reaction chamber 3. A plasma may be excited within the reaction chamber 3 by applying, for example, HRF power (e.g., 13.56 MHz, 27 MHz, or 60 MHz) and/or low frequency power from a RF generator 25 to one electrode (e.g., electrode 4) via RF matcher and electrically grounding the other electrode (e.g., susceptor heater 2).

The susceptor heater 2 may be disposed in the reaction chamber 3, and a temperature of a substrate 1 placed thereon may be kept at a desired temperature. The susceptor heater may comprise aluminum when the susceptor heater is used for deposition process. The susceptor heater may comprise a ceramic when the susceptor heater is used for annealing process. The ceramic may comprise at least one of Al2O3, AlN, SiC, or Si3N4.

The electrode 4 may serve as a gas distribution device, such as a shower plate. Reactant gas, dilution gas, if any, precursor gas, and/or the like may be introduced into reaction chamber 3 using one or more of a gas line 20, a gas line 21, and a gas line 22, respectively, and through the shower plate 4. Although illustrated with three gas lines, the reactor system 500 may include any suitable number of gas lines.

In the reaction chamber 3, a circular duct 13 with an exhaust line 7 may be provided, through which gas in the interior 11 of the reaction chamber 3 may be exhausted. Additionally, a transfer chamber 5, disposed below the reaction chamber 3, may be provided with a seal gas line 24 to introduce seal gas into the interior 11 of the reaction chamber 3 via the interior 16 (transfer zone) of the transfer chamber 5, wherein a separation plate 14 for separating the reaction zone and the transfer zone may be provided (a gate valve through which a wafer is transferred into or from the transfer chamber 5 is omitted from this figure). The transfer chamber may be also provided with an exhaust line 6. In some embodiments, the deposition and treatment steps may be performed in the same reaction space, so that two or more (e.g., all) of the steps may continuously be conducted without exposing the substrate to air or other oxygen-containing atmosphere.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A substrate processing apparatus, comprising:
a plurality of anneal chambers;
a shared RF generator configured to generate a plasma to the anneal chambers;
wherein the shared RF generator is electrically coupled to the anneal chambers via a RF divider;
wherein the RF divider is provided with a plurality of RF cables, each of the RF cables is electrically coupled to each of the anneal chambers respectively.

2. The substrate processing apparatus according to claim 1, wherein the plasma is generated before a substrate is provided to the anneal chamber.

3. The substrate processing apparatus according to claim 1, wherein a temperature of the anneal chamber is between 100° C. and 800° C.

4. The substrate processing apparatus according to claim 1, wherein the anneal chamber further comprising a susceptor heater constructed and arranged to support a substrate, wherein the susceptor heater comprises a ceramic.

5. The substrate processing apparatus according to claim 1, wherein the susceptor heater comprises at least one of Al2O3, AlN, SiC, or Si3N4.

6. The substrate processing apparatus according to claim 1, further comprising a shared RF matcher disposed between the shared RF generator and the RF divider.

7. The substrate processing apparatus according to claim 1, further comprising an ammeter disposed between the shared RF generator and the RF divider.

8. The substrate processing apparatus according to claims 7, wherein the ammeter is configured to measure a current.

9. The substrate processing apparatus according to claim 8, further comprising a controller electrically coupled to the ammeter, wherein the controller is configured to generate an alert when an output of the ammeter deviates from a normal value.

10. The substrate processing apparatus according to claim 9, wherein the controller is configured to stop an operation of the shared RF generator based on the output of the ammeter.

11. The substrate processing apparatus according to claim 1, further comprising:
a plurality of deposition chambers;
a plurality of RF generator configured to generate a 2^{nd} plasma to the deposition chambers;
wherein each of the RF generators is electrically coupled to each of the deposition chambers respectively.

12. The substrate processing apparatus according to claim 11, wherein the 2^{nd} plasma is generated when a gapfill deposition process is performed in the deposition chamber.

13. The substrate processing apparatus according to claim 11, wherein a temperature of the deposition chamber is between 50° C. and 550° C.

14. The substrate processing apparatus according to claim 11, wherein the deposition chamber further comprising a 2^{nd} susceptor heater constructed and arranged to support a substrate, wherein the 2^{nd} susceptor heater comprises aluminum.

15. The substrate processing apparatus according to 11, wherein an anneal chamber module comprises the plurality of anneal chambers;
wherein a deposition chamber module comprises the plurality of deposition chambers.

16. The substrate processing apparatus according to claim 15, further comprising:
a substrate handling chamber having a plurality of sides,
wherein the anneal chamber module is attached to one of the sides;
wherein the deposition chamber module is attached to one of the sides;
a backend robot for transferring a substrate, the backend robot being disposed in the substrate handling chamber; and
a load lock chamber for loading or unloading the substrate, the load lock chamber being attached to one of the sides.
